(19) United States
(12) Patent Application Publication
(10) Pub. No.: US 2005/0179111 A1
(43) Pub. Date: Aug. 18, 2005

(54) Semiconductor device with low resistive path barrier

(76) Inventor: Iwen Chao, Sacramento, CA (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/779,379

(22) Filed: Feb. 12, 2004

(51) Int. Cl. H01L 29/00; H01L 21/8238

(52) U.S. Cl. 257/510; 438/221

(57) ABSTRACT

A semiconductor device formed on a conductivity region and isolated by a low resistive path barrier and a deep trench isolation structure.

### FIELD OF THE INVENTION

The present invention relates to, but is not limited to, electronic devices, and in particular, to the field of semiconductor devices.

### BACKGROUND OF THE INVENTION

In the current state of integrated circuit technology, semiconductor devices have widespread applications. These devices include, for example, complementary metal-oxide semiconductor (CMOS), bipolar complementary metal-oxide semiconductor (BiCMOS), n-type metal-oxide semiconductor (NMOS), p-type metal-oxide semiconductor (PMOS), and the like. When these devices are incorporated into integrated circuits, they are typically formed on conductivity regions (p-type and/or n-type well) of a substrate.

These devices may be used, for example, in wireless and optical communication systems and in logic applications such as in the design of very large scale integrated circuits, for example, microprocessors, microcontrollers and other integrated systems. As these devices become incorporated into these densely packed circuits, the devices are becoming smaller requiring less power to operate. Further, these devices are increasingly being used in high frequency operations such as in communication systems.

### BRIEF DESCRIPTION OF DRAWINGS

The present invention will be described by way of exemplary embodiments, but not limitations, illustrated in the accompanying drawings in which like references denote similar elements, and in which:

FIG. 1 illustrates a cross-sectional view of a conventional CMOS.

FIG. 2A illustrates a semiconductor device structure with low resistive path barrier and deep trench isolation according to some embodiments of the invention.

FIG. 2B illustrates a particular embodiment of the semiconductor device structure of FIG. 2A, in particular, a CMOS with buried layer, plug and deep trench isolation structures.

FIG. 3 illustrates the NMOS portion of FIG. 2B in further detail, and in particular, the movement of noise according to an embodiment of the invention.

FIG. 4 illustrates a CMOS with low resistive path barrier and deep trench isolation structures surrounding only the NMOS portion according to an embodiment of the invention.

FIG. 5 is a block diagram of an example system, according to some embodiments of the invention.

### DETAILED DESCRIPTIONS OF EMBODIMENTS OF THE INVENTION

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in block diagram form in order not to obscure the disclosed embodiments of the present invention.

The terms chip, integrated circuit, semiconductor device and microelectronic device are often used interchangeably in this field. The present invention relates to the manufacture of chips, integrated circuits, semiconductor devices and microelectronic devices as these terms are commonly understood in the art.

According to embodiments of the present invention, a novel structure for a semiconductor device is proposed. The device may incorporate low resistive path barrier and deep trench isolation structure to reduce the amount of noise reaching the device. Such a device, when incorporated into an integrated circuit (IC) may operate in high frequency and/or high-density environments without interference from noise and cross talk generated by other IC components and/or systems.

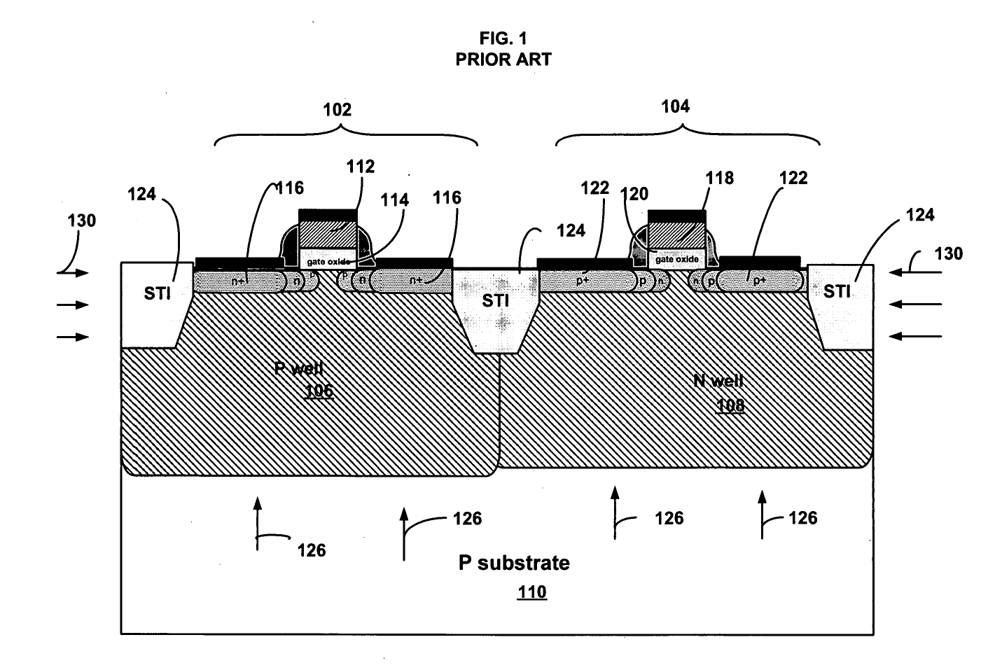

In order to appreciate various aspects of the present invention, a complementary metal-oxide semiconductor (CMOS) formed on a substrate of a die or chip is now presented. FIG. 1 shows a CMOS 100 having two field effect transistors (FETs), a NMOS transistor 102 and a PMOS transistor 104 formed on two conductivity regions, a p-type conductivity region 106 (i.e., p-well) and a n-type conductivity region 108 (i.e., n-well). The conductivity regions are formed on top of a substrate, in this case, a p-type substrate 110. The NMOS transistor 102 has a gate electrode 112 formed on a gate dielectric gate layer 114 and a pair of n-type source/drain regions 116 formed on laterally opposite sides of the gate electrode 112. Similarly, the PMOS transistor 104 may contain a gate electrode 118 formed on a gate dielectric gate layer 120 and a pair of p-type source/drain regions 122 formed on laterally opposite sides of the gate electrode 118. Both of the transistors 102 and 104 may be surrounded by shallow trench isolation (STI) 124. The shallow trench isolation 124 may be filled with noise isolating material such as a dielectric or an insulation material. The shallow trench isolation 124 may isolate the transistors 102 and 104 from certain noises, particularly noises that propagate along or near the surface of the die (to be further discussed below).

The noise that may propagated on the surface of an IC and through the substrate are depicted in FIG. 1, where the operation of the NMOS and PMOS transistors 102 and 104 may be hindered by both surface and substrate noise 130 and 126. This may result even with the presence of shallow trench isolation 124. This is because although the shallow trench isolation 124 may provide some isolation from surface noise, such structures may not be an effective technique for isolating the transistors 102 and 104 from substrate noise 126.

Other structures may offer some limited protection from noise, particularly noise that is associated with low frequencies (i.e., less than 10 GHz). For example, guard ring, silicon on insulation (SOI) and deep nwell structures may offer some isolation from low frequency noise. However, none of these structures, implemented individually, appear to be very effective against high frequency noise.

Compounding this problem is the fact that many of today's IC systems operate at increasingly higher frequencies. For instance, some communication circuits such as circuits associated with wireless and optical communication systems are operating at 10 GHz or 40 GHz. Noise associated with such circuits may be more penetrating then noise associated with lower frequencies. As a result, certain structures, such as deep n-well, which offer capacitive properties, may lose their effectiveness to isolate noise above 10 GHz. Even shallow trench isolation 124, which may be effective against low frequency surface noise, may not be effective against surface noise if the surface noise is high frequency noise. For at least these reasons, the challenge of designing IC components may be particularly difficult when such components must work in high frequency/high density environments.

In brief, according to various embodiments of the invention, a structure is presented herein which, among other things, provides noise isolation to semiconductor devices, such as metal-oxide semiconductor field effect transistors (MOSFETs), by surrounding the semiconductor devices with a low resistive path barrier and a deep trench isolation structure. A deep trench isolation is first formed around the semiconductor device, which may force noise to go deep into the underlying substrate thus dissipating some of the noise into the substrate. Isolation may further be enhanced by further surrounding the semiconductor device with a low resistive path barrier, which offers very good AC ground at high frequency and may form a low resistive path that may dissipate any noise reaching the barrier.

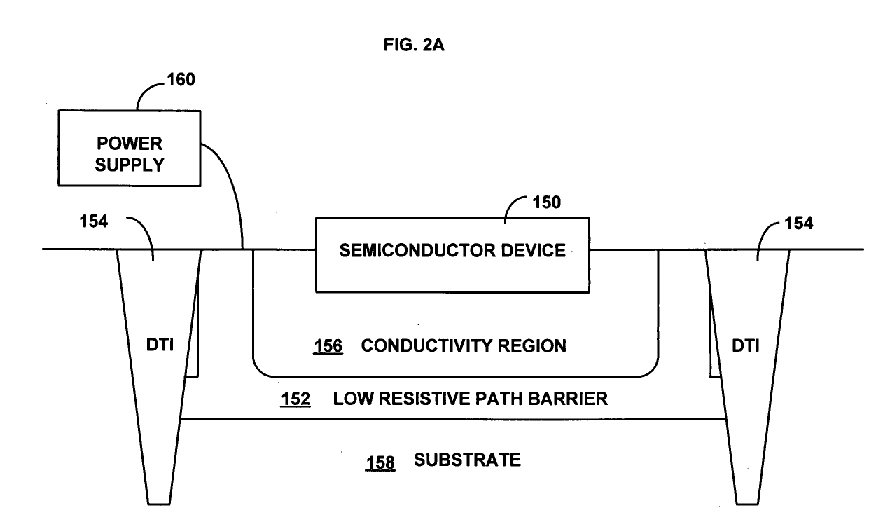

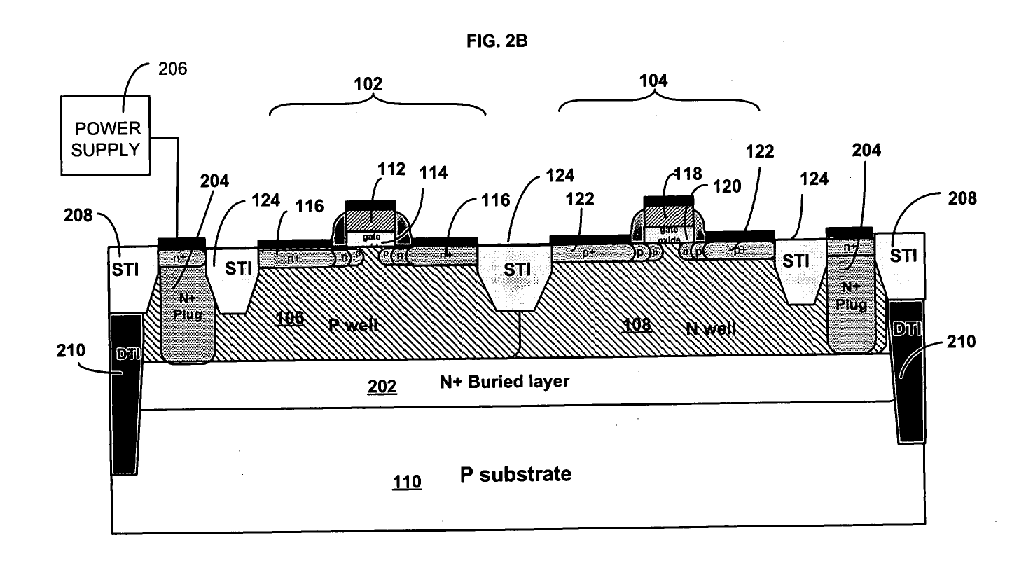

FIG. 2A shows a semiconductor device 150 isolated from external noise by a low resistive path barrier 152 and deep trench isolation 154 according to an embodiment of the present invention. The semiconductor device 150 may be a NMOS, a PMOS, a CMOS, a BiCMOS, and the like. The semiconductor device 150 may be formed on a conductivity region 156 (i.e., well region). The conductivity region 156 may actually include more than one type of conductivity region such as both an n-type and a p-type conductivity region. A low resistive path barrier 152 surrounds the conductivity region 156 isolating the conductivity region 156 from the underlying substrate 158. Depending on the type of semiconductor device 150 (e.g., NMOS, PMOS, and the like), the substrate 158 may be biased to the highest or lowest (typically 0 volts) voltage possible. For the embodiment, the low resistive path barrier 152 may be coupled to a power supply 160. The substrate 158, among other things, supporting the semiconductor device 150 and the conductivity region 156 and may be either a p-type or an n-type substrate. The low resistive path barrier 152 may comprise of N+ or P+ material. The “+” designation is meant to indicate that the N or P doped material is highly doped. For example, according to some embodiments, the low resistive path barrier 152 may have doping concentration in the order of ten times the concentration of the conductivity region 156. However, in other embodiments, the low resistive path barrier 152 may have even higher or lower doping concentrations. The low resistive path barrier 152 may be coupled to a power supply 160, such as a DC power supply. A deep trench isolation 154 surrounds the low resistive path barrier 152 extending down into the substrate 158. The deep trench isolation 154 may be filled with a dielectric or insulation material.

In order to isolate the semiconductor device 150 from noise generated by external IC components (not shown), the deep trench isolation 154 may force the noise to go deep into the substrate 158 where some of the noise may be dissipated. Noise that is not dissipated by the substrate 158 and gets around the deep trench isolation 154 or noise that propagates deep in the substrate 158 and move towards the semiconductor device 150 and conductivity region 156 may be collected by the low resistive path barrier 152. The low resistive path barrier 152 may then redirect the noise towards the power supply 160, which may then dissipate the noise.

Referring to FIG. 2B, which shows a CMOS with low resistive path barrier and deep trench isolation according to some embodiments of the invention. The CMOS 200, as with the CMOS of FIG. 1, having a NMOS transistor 102 and a PMOS transistor 104 formed on two conductivity regions, a p-type conductivity region 106 (i.e., p-well) and a n-type conductivity region 108 (i.e., n-well). The conductivity regions 106 and 108 may be formed on top of a substrate, in this case, a p-type substrate 110. The NMOS transistor 102 may contain a gate electrode 112 formed on a gate dielectric gate layer 114 and a pair of n-type source/drain regions 116 formed on laterally opposite sides of the gate electrode 112. Similarly, the PMOS transistor 104 may contain a gate electrode 118 formed on a gate dielectric gate layer 120 and a pair of p-type source/drain regions 122 formed on laterally opposite sides of the gate electrode 118. Each of the transistors 102 and 104 may be surrounded by shallow trench isolation 124.

A low resistive path barrier comprising of buried layer 202 and plug 204 surrounds the transistors 102 and 104 and the conductivity regions 106 and 108. The plug 204 may be coupled to a power supply 206. The buried layer 202 may comprise of N+ doped material, and may be formed between the conductivity regions 106 and 108 and the p-substrate 110. The doping concentration of the conductivity regions (well regions) 106 and 108 for a CMOS device, such as the one depicted in FIG. 2B, will typically be about 2×10¹⁷ cm⁻³. According to some embodiments, the plug 204 may have a doping concentration of about 5×10¹⁸ cm⁻³ and a resistivity of about 0.01 ohm-cm while the buried layer 202 may have a doping concentration greater than 1×10¹⁹ cm⁻³ and a resistivity of about 0.005 ohm-cm.

The plug 204, which may comprise of N+ doped material, may encircle the transistors 102 and 104 and the conductivity regions 106 and 108. Both the N+ buried layer 102 and the N+ plug 104 may be formed through high dose N type implant (P or As). The N+ plug 204 may extend from the surface down to the N+ buried layer 202. An additional outside shallow trench isolation 208 may be formed outside of the plug 204 on the opposite side from the CMOS.

At the bottom of the outside shallow trench isolation 208, a deep trench isolation 210 may be formed. The deep trench isolation 210 may completely encircle or surround the plug 204 and the CMOS components (e.g., transistors and conductivity regions). The deep trench isolation 210 may extend down into the p-substrate 110. According to one embodiment, the deep trench isolation 210 may extend down to a depth of about 5 μm (as opposed to shallow trench isolation structures, which typically only extend down to a depth of 0.5 μm). The deep trench isolation 210 may be filled with a dielectric or insulation material that may be different from the material that fills the outside shallow trench isolation 208. In some embodiments, the buried layer 202 and the plug 204 may be formed through high dose N type implant (P or As) in a silicon substrate.

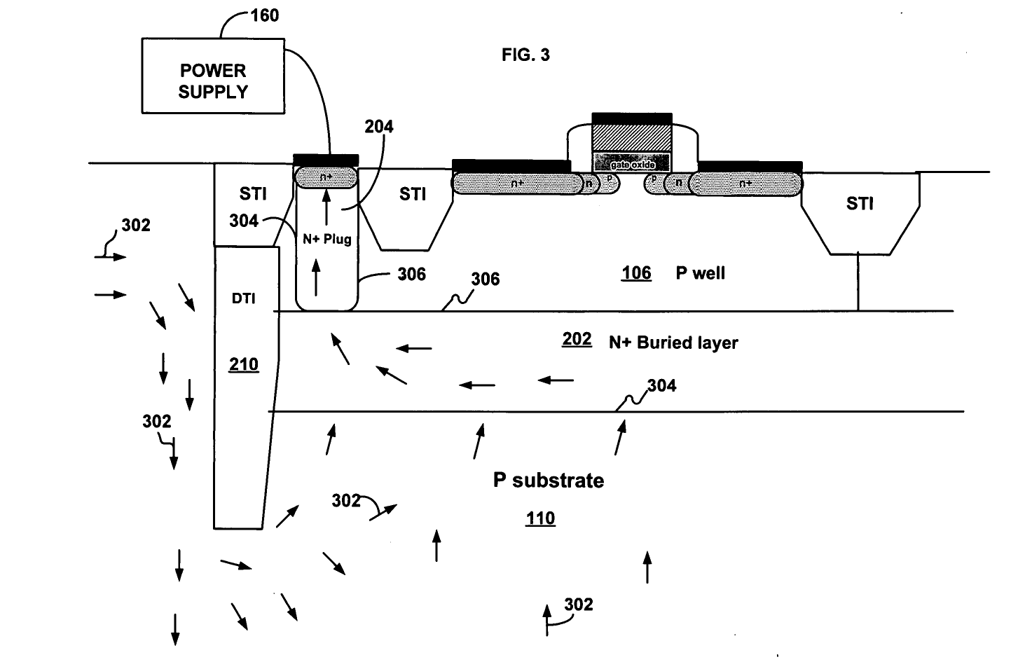

FIG. 3 illustrates some of the concepts introduced above and shows the movement of noise on the NMOS side of the CMOS structure of FIG. 2. Noises 302 that propagate through the p-substrate 110 may be forced to go deep into the p-substrate 110 as a result of the deep trench isolation 210. Some of the noises 302 may dissipate into the p-substrate while other noises 302 may travel towards the CMOS components. Two capacitive decoupling junctions are formed when the low resistive path barrier (i.e., plug 204 and buried layer 202) is formed between the p-well conductivity region 106 and the p-substrate 110. The first capacitive decoupling junction 304 is located at the p-substrate/buried layer/plug junction, and the second capacitive decoupling junction 306 is located at the p-type conductivity region/buried layer/plug junction. The junctions may be formed because of the formation of pn junctions at the interfaces between the low resistive path barrier (N+ buried layer 202 and N+ plug 204) and the p-type conductivity region 106, and between the low resistive path barrier and the p-substrate 110. These junctions 304 and 306 may help reduce noise that enters the low resistive path barrier 202 and 204. Any noise which is able to enter the low resistive path barrier 202 and 204 may move along this low resistive path that is formed by the junctions 304 and 306 and the low resistive path barrier 202 and 204. The noise may then travel to the power supply 206 where it is dissipated. Note that although the embodiment described above relate to a CMOS, those skilled in the art will recognize that novel aspects of the invention may be incorporated into the structures of other types of semiconductor devices such as BiCMOS, NMOS, PMOS, and the like.

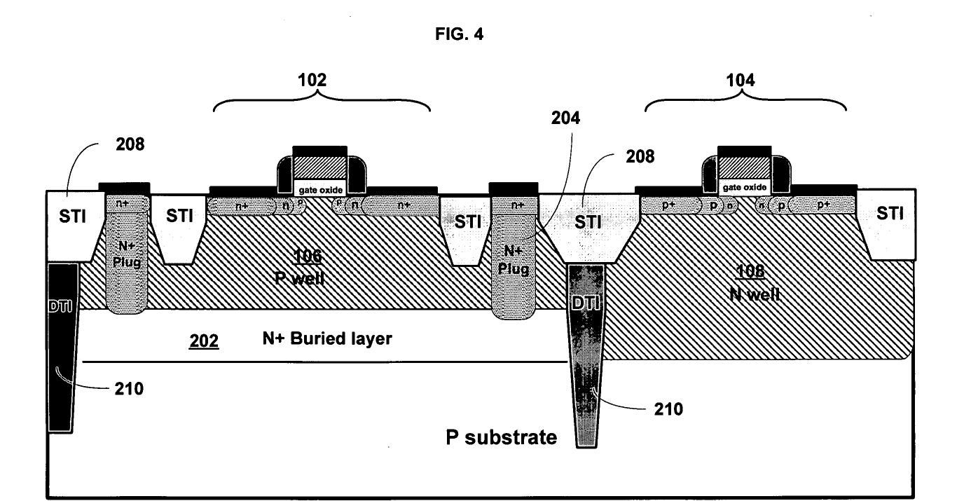

FIG. 4 illustrates a CMOS with a buried layer underneath only the p-well side of the CMOS according to another embodiment. For the embodiment, N+ buried layer 202 is only under the p-well side (i.e., NMOS 102) of the CMOS and does not extend to the n-well side (i.e., PMOS 104) of the CMOS. Further, the deep trench isolation 210 and the outside shallow trench isolation 208 only surrounds the NMOS 102 portion of the CMOS. In the CMOS structure depicted in FIG. 2B, the N+ buried layer 202 extends underneath both the p-well 106 and the n-well 108. Since many CMOS circuits only use NMOS for high frequency operations only the NMOS portion of the circuit may be isolated from the noise that propagates through the substrate. The embodiment depicted in FIG. 4 may have lower impact to circuit complexity and area requirement than the CMOS structure depicted in FIG. 2B.

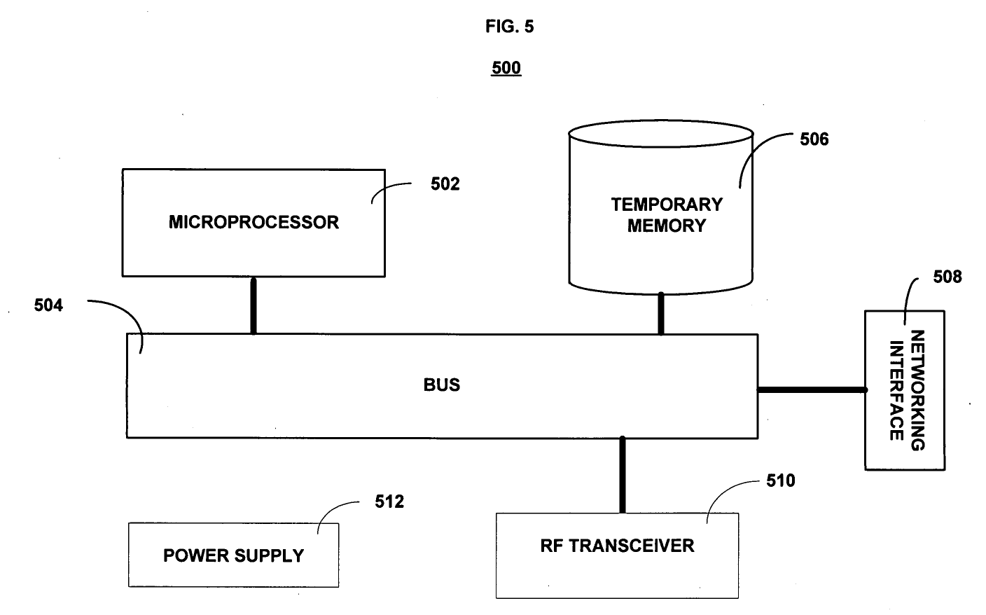

Referring to FIG. 5 showing a system 500 in accordance with some embodiments. The system 500 includes a microprocessor 502 that may be coupled to a bus 504. The system 500 may further include a temporary memory 506, a network interface 508, a RF transceiver 510 and a power supply 512. Although the power supply 512 is depicted standing alone, it may be coupled directly or indirectly to one or more of the system components (i.e., temporary memory 506, network interface 508, RF transceiver 510, and the like). In an alternative embodiment, the RF transceiver 510 may be part of the network interface 508. One or more of the above enumerated elements, such as microprocessor 502, memory 506, and so forth, may contain one or more semiconductor devices that advantageously incorporate the low resistive path barrier and deep trench isolation structure described above.

Depending on the applications, the system 500 may include other components, including but not limited to non-volatile memory, chipsets, mass storage (such as hard disk, compact disk (CD), digital versatile disk (DVD), graphical or mathematic co-processors, and so forth.

One or more of the system components may be located on a single chip such as a SOC. In various embodiments, the system 500 may be a personal digital assistant (PDA), a wireless mobile phone, a tablet computing device, a laptop computing device, a desktop computing device, a set-top box, an entertainment control unit, a digital camera, a digital video recorder, a CD player, a DVD player, a network server, or device of the like.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the embodiments of the present invention. Therefore, it is manifestly intended that this invention be limited only by the claims.

1. An apparatus, comprising:
a semiconductor device formed on a conductivity region; and
a low resistive path barrier formed surrounding the conductivity region to isolate the conductivity region from a substrate that supports the conductivity region and the low resistive path barrier.

2. The apparatus of claim 1, further comprises of a deep trench isolation formed surrounding the low resistive path barrier on the opposite side of the conductivity region.

3. The apparatus of claim 2, wherein the deep trench isolation extends into the substrate.

4. The apparatus of claim 1, wherein the conductivity region is at least one of n-type and p-type conductivity regions.

5. The apparatus of claim 1, wherein the semiconductor device is a selected one of CMOS, BiCMOS, NMOS and PMOS.

6. The apparatus of claim 1, wherein the low resistive path barrier is coupled to a power supply.

7. The apparatus of claim 1, wherein the substrate is selected from one of p-type and n-type substrate.

8. The apparatus of claim 1, wherein the low resistive path barrier comprises of a plug coupled to a buried layer.

9. The apparatus of claim 8, wherein the plug is coupled to a power supply.

10. The apparatus of claim 1, wherein the low resistive path barrier comprises a selected one of N+ and P+ doped material.

11. The apparatus of claim 1, wherein the deep trench isolation comprises of a selected one of a dielectric and an insulation material.

12. The apparatus of claim 1, wherein the substrate is biased to 0 volts.

13. The apparatus of claim 1, wherein the low resistive path barrier comprises of a first capacitive decoupling junction located at an interface between the low resistive path barrier and the conductivity region, and a second capacitive decoupling junction located at an interface between the low resistive path barrier and the substrate.

14. The apparatus of claim 7, wherein the plug having a resistivity of about 0.01 ohm-cm and the buried layer having a resistivity of about 0.005 ohm-cm.

15. The apparatus of claim 2, wherein the deep trench isolation having a depth of about 5 μm.

16. A method comprising:
forming a semiconductor device on a conductivity region; and
forming a low resistive path barrier that surrounds the conductivity region to isolated the conductivity region from a substrate that supports the conductivity region and the low resistive path barrier,

17. The method of claim 16, further comprises forming a deep trench isolation surrounding the low resistive path barrier on the opposite side of the conductivity region.

18. The method of claim 16, further comprises coupling the low resistive path barrier to a power supply.

19. The method of claim 16, wherein the semiconductor device is a selected one of CMOS, BiCMOS, NMOS and PMOS.

20. The method of claim 16, wherein the conductivity region is at least one of n-type and p-type conductivity regions.

21. The method of claim 16, wherein the formed low resistive path barrier comprises a plug coupled to a buried layer.

22. The method of claim 21, further comprises coupling the plug to a power supply.

23. The method of claim 17, wherein forming of deep trench isolation further comprises filling the deep trench isolation with a selected one of a dielectric or a insulation material.

24. The method of claim 16, wherein the formed low resistive path barrier comprises a selected one of N+ and P+ doped material.

25. A system, comprising:
an integrated circuit having a semiconductor device formed on a conductivity region, including
a low resistive path barrier formed surrounding the conductivity region to isolated the conductivity region from a substrate that supports the conductivity region and the low resistive path barrier;
a bus coupled to the integrated circuit; and
a networking interface coupled to the bus.

26. The system of claim 25, further comprises a deep trench isolation formed surrounding the low resistive path barrier on the opposite side of the conductivity region;

27. The system according to claim 25, wherein the low resistive path barrier is coupled to a power supply.

28. The system according to claim 25, wherein the semiconductor device is selected from one of CMOS, BiCMOS, NMOS and PMOS.

29. The system according to claim 25, wherein the low resistive path barrier comprises a selected one of N+ and P+ doped material.

30. The system according to claim 25, wherein the low resistive path barrier comprises of a plug and a buried layer.
